(19) United States
(12) Patent Application Publication
(10) Pub. No.: US 2022/0092016 A1
(43) Pub. Date: Mar. 24, 2022

(54) OFF-PACKAGE HIGH DENSITY, HIGH BANDWIDTH MEMORY ACCESS USING OPTICAL LINKS

(71) Applicant: Intel Corporation, Santa Clara, CA (US)

(72) Inventors: Mahesh K. KUMASHIKAR, Bangalore (IN); Dheeraj SUBBAREDDY, Portland, OR (US); Anshuman THAKUR, Beaverton, OR (US); MD Altaf HOSSAIN, Portland, OR (US); Ankireddy NALAMALPU, Portland, OR (US); Casey G. THIELEN, Chandler, AZ (US); Daniel S. KLOWDEN, Portland, OR (US); Kevin P. MA, Beaverton, OR (US); Sergey Yuryevich SHUMARAYEV, Los Altos Hills, CA (US); Sandeep SANE, Chandler, CA (US); Conor O'KEEFFE, Co. Cork (IE)

(21) Appl. No.: 17/031,823

(22) Filed: Sep. 24, 2020

(51) Int. Cl. G06F 13/42; G06F 13/40; G06F 13/16; G11C 7/10

(52) U.S. Cl. CPC G06F 13/4234; G06F 13/4068; G11C 7/1081; G11C 7/1054; G06F 13/1678

(57) ABSTRACT

Embodiments herein relate to systems, apparatuses, or techniques for using an optical physical layer die within a system-on-a-chip to optically couple with an optical physical layer die on another package to provide high-bandwidth memory access between the system-on-a-chip and the other package. In embodiments, the other package may be a large optically connected memory device that includes a memory controller coupled with an optical physical layer die, where the memory controller is coupled with memory. Other embodiments may be described and/or claimed.

### FIELD

Embodiments of the present disclosure generally relate to the field of packages that access high-density memory, and in particular using optical links to access memory off-package.

### BACKGROUND

Artificial intelligence (AI) workloads will continue to require high memory bandwidth to exploit high-density compute structures in graphical process units (GPUs), field programmable gate arrays (FPGAs), and central processing units (CPUs).

### BRIEF DESCRIPTION OF THE DRAWINGS

FIG. 1 illustrates example of a legacy implementation of in-package high bandwidth memory (HBM), in accordance with embodiments.

FIG. 2 illustrates a detailed example of off-package, high-density, high bandwidth memory access using a single optical link, in accordance with embodiments.

FIG. 3 illustrates an example system of multiple system-on-a-chip (SOC) packages interacting with multiple large optically connected memory device (LOCM) packages, in accordance with embodiments.

FIG. 4 illustrates an example of a SOC coupled with an LOCM using an external laser diode, in accordance with embodiments.

FIG. 5 illustrates an example process implementing a system that includes off-package, high-density, high bandwidth memory access using optical link, in accordance with embodiments.

FIG. 6 schematically illustrates a computing device, in accordance with embodiments.

### DETAILED DESCRIPTION

Embodiments of the present disclosure may generally relate to systems, apparatus, and/or processes directed to off-package, high-density, high-capacity, high bandwidth memory access using an optical link. From a legacy perspective, embodiments are directed to achieving on-package like bandwidth and bandwidth density using off-package optical interconnects by integrating them with optical physical (PHY) components and fiber in-package. In particular, artificial intelligence workloads can benefit from high memory bandwidth to exploit high-density compute architectures in GPUs, FPGAs, and CPUs within SOCs.

Legacy implementations include high bandwidth memory (HBM) devices integrated on package with a CPU. Legacy implementations may also include off-package memory interconnects like double data rate memory (DDR). These legacy implementations have both low bandwidth and low bandwidth density, but provide connection higher capacity memory. In order to provide higher bandwidth in these legacy scenarios, a large number of DDR channels may need to be integrated on the SOC. However, this approach increases die area, package area, and also increases package escape complexity due to the increased number of signals out of the package that must be managed. The complexity can involve additional package substrate layers, additional printed circuit board (PCB) layers and/or more advanced, and costly, technology at the package or PCB level.

In legacy implementations, on-package integration using short reach interconnect may provide high bandwidth to SoCs. Interposer or embedded multi-die interconnect bridge (EMIB) based on-package interconnects provide both high bandwidth density and high bandwidth interconnect between memory and the SOC in an area-efficient manner. However, in these legacy implementations the capacity of such memory is limited to small amount of memory, for example 16G, per device, due to package form factor constraints. Other legacy implementations to achieve higher capacity memory on package may be accomplished at a system level by scaling out SOC packages with integrated memory.

In embodiments described herein, an optical PHY die on-package may be connected to an SOC memory interface using interconnects like EMIB or an interposer. The optical PHY die may connect to one or more single mode optical fibers to provide an off-package interconnect. This optical link may be connected to a large capacity memory device (LOCM) that has an integrated optical PHY and memory controller to connect to the memory devices on the LOCM. In embodiments, this approach provides high bandwidth density, energy efficiency, and low latency that results on-package like interconnect performance, or greater, with off-package memory. Embodiments also provide disaggregation of non-package memory devices. In addition, this disaggregated memory may be at a further physical distance due to the low loss nature of the optical link, yet still behave from an electrical and performance perspective like it is on-package memory. In embodiments, this approach gives flexibility in building LOCMs in terms of their form factor and space allocation within a system.

Embodiments also have the advantage of reducing the number of HBM devices integrated on package, which reduces the SOC cost and complexity. The LOCM may have a very high-capacity that is provided through a very high optical bandwidth. The LOCM is physically disaggregated from the SOC and allows compute SOCs to be replaced independent of any change to the LOCM. Also in embodiments, the LOCM, being physically far from the SOC, may result in thermal benefits to the SOC in comparison to legacy implementations where close proximity of HBM devices in the SOC may create thermal issues that affect SOC power and performance. Finally, because the LOCM is physically disaggregated from the SOC, it provides better serviceability for faulty memory devices. In contrast, when in legacy implementations HBM devices go bad, for example due to infant mortality or other reliability issues, the disabled HBM results in performance loss, or the need to replace the entire SOC package.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

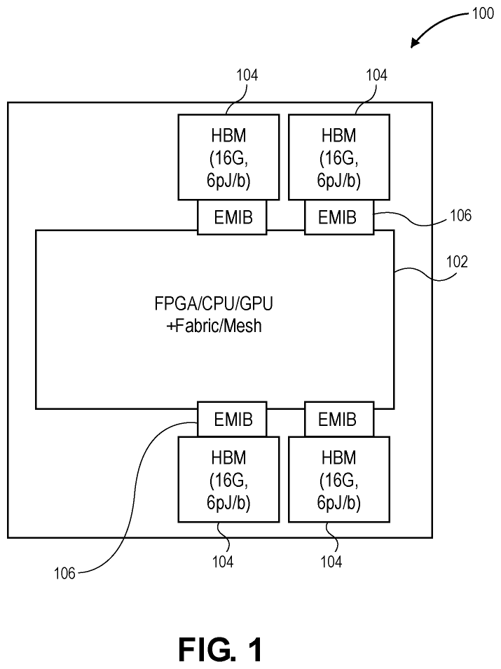

FIG. 1 illustrates example of a legacy implementation of in-package HBM, in accordance with embodiments. SOC 100 is a legacy implementation that includes a compute chip 102 coupled to one or more HBM via an EMIBs 106. In embodiments the compute chip 102 may be a FPGA, a CPU, a GPU, or any ASIC or accelerated processing unit (APU) that supports a fabric, mesh, or acceleration function, or some other compute device. In embodiments, the compute chip 102 may be a chip that includes non-compute functions. The HBMs 104 may include a 16 gigabit memory accessible by the compute chip 102, and may provide both high bandwidth density and high bandwidth interconnect, via the EMIB 106 or an interposer, between HBM 104 and the chip 102 in an area efficient manner. However, the capacity of the HBM 104 memory is limited to small amount of memory, for example, 16 G per device, due to SOC 100 form factor constraint. Legacy HBM 104 devices may provide 400 GB/s of bandwidth along a silicon edge, which may be referred to as a “shoreline,” of 6.5 mm at 0.5 pJ/b energy. The legacy HBM device may consume 6 pico-Joules per bit (pJ/b), contributing to the thermal performance of the legacy SOC 100.

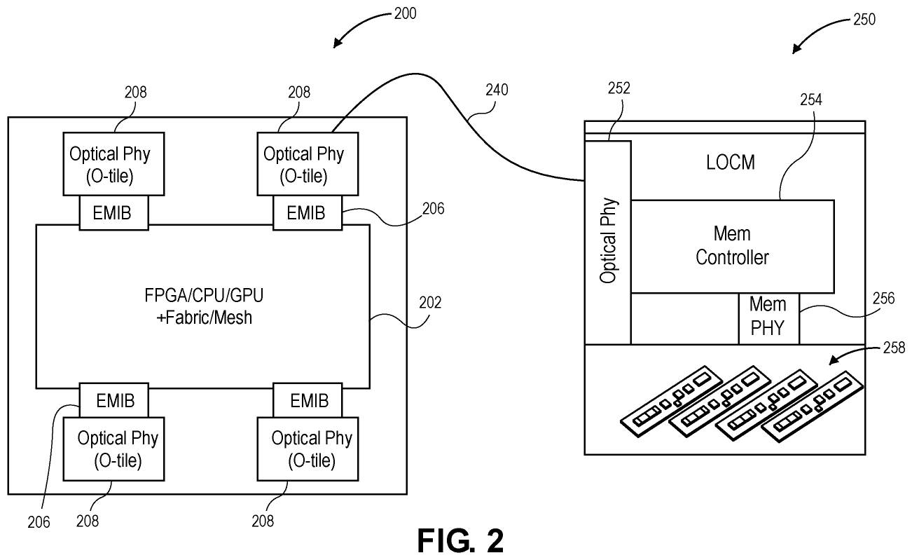

FIG. 2 illustrates a detailed example of an off-package, high-density, high bandwidth memory access using a single optical link, in accordance with embodiments. SOC 200 includes a chip 202, which may be similar to chip 102 of FIG. 1, that is connected to one or more optical PHY dies 208 via multiple EMIBs 206, which may be similar to EMIBs 106 of FIG. 1. In embodiments, the chip 202 and the optical PHY dies 208 may be connected through a silicon interposer (not shown). In embodiments, optical PHY dies (not shown) may be integrated directly into the chip 102 to eliminate the need for a separate PHY dies 208.

The optical PHY dies 208 include optical controller logic, optical converters, and ports into which an optical fiber 240 may be physically coupled. Optical fiber 240 that is attached to the optical PHY die 208 provides an off-package connection with the SOC 200. Legacy optical PHY dies 208 may provide 256-512 GB/s bandwidth within a 9 mm shoreline. Future generations of PHY dies 208 may improve this bandwidth to 1 TB/s bandwidth or more. Also, note that the bandwidth and bandwidth density of the SOC 200 implementation matches or exceeds the HBM bandwidth as shown in SOC 100 of FIG. 1, at around 5 pJ/b energy efficiency. In embodiments, while the interconnect energy efficiency is higher with an optical link, at the SOC 200 package level, energy efficiency remains the same or better because the HBM 104 memory is not used.

In embodiments, the optical link 240 connects to a large memory device, LOCM 250. The LOCM 250 includes an optical PHY die 252 that connects with the optical fiber 240. The LOCM 250 includes a memory controller 254 that may be coupled with a memory PHY die 256 to access memory devices 258 in the LOCM 250.

During operation of the SOC 200 coupled with the LOCM 250, there is an incremental latency increase for electrical to optical conversion, transit of the signal through fiber, and optical to electrical conversion. This incremental latency in one direction may be 15-25 nS for 1-3 m of optical fiber length. In embodiments, it may be important to keep latency increase as minimal as possible as the SOC 200 may need buffer (not shown) size increases to account for such latency increments. A benefit of using an optical link is low loss, which enables signaling without the need of expensive error correction mechanisms such as forward error correction (FEC). Such error correction schemes are a cause of high latency. As an example, legacy-copper based high speed SERDES with FEC incur additional 70-80 nS just for error correction. Table 1 below shows typical overall latency numbers with LOCM in comparison with baseline memory technology.

TABLE 1

| | Typical read | Latency with | |
|---|---|---|---|
| Memory | latency | LOCM | Comments |
| HBM | 250-300 nS | 280-350 nS | Baseline latency higher |
| | | | for high throughput |
| | | | compute; Incremental |
| | | | latency can be within 15%; |
| | | | Can be absorbed with small |
| | | | buffer increase |
| DDR | 80-130 nS | 110-180 nS | Baseline latency is lower |
| | | | and optimized for |
| | | | general compute; |
| | | | Incremental latency can |
| | | | be within 40%; Needs |
| | | | large buffer addition |

The combination of bandwidth, bandwidth density, latency, and energy efficiency of optical PHY 208 implementation within SOC 200 provides embodiments that make the performance of the off-package optical interconnect equal to or better than an on-package HBM 104 interconnect. In embodiments, memory devices 258 connected LOCM 250 provide high-capacity and bandwidth that matches the optical link 240. In embodiments, different LOCM 250 with different memory channel counts may be designed to provide different capacity and bandwidth constraints.

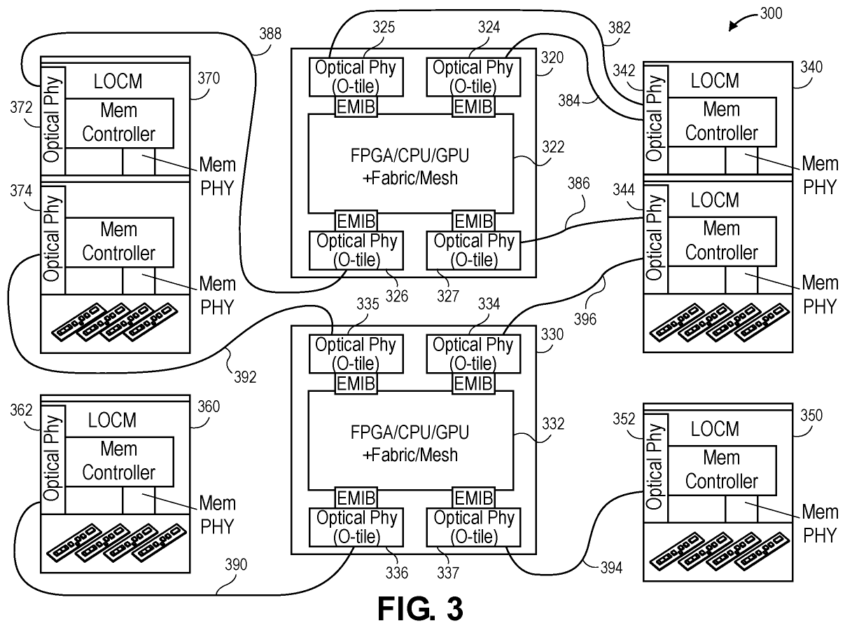

FIG. 3 illustrates an example system of multiple SOC packages interacting with multiple LOCM packages, in accordance with embodiments. System 300 includes two compute SOCs 320, 330, that may be connected via optical fiber to LOCMs 340, 350, 360, 370 in a one to one, one to many, many to many, or many to one topology. Compute SOC 320 includes compute chip 322 that is electrically coupled with optical PHY chips 324, 325, 326, 327. Compute SOC 330 includes compute chip 332 that is electrically coupled with optical PHY chips 334, 335, 336, 337. System 300 also includes four LOCMs 340, 350, 360, 370 with one or more optical PHY dies 342, 344, 352, 362, 372, 374.

For example, one compute SOC 320 may have multiple optical PHY dies 324, 325 coupled with one LOCM 340 using optical links 382, 384. In another example, one compute SOC 320 may have multiple optical PHY dies 324, 325, 326, 327 that couple with multiple LOCM 340, 370 using optical links 382, 384, 386, 388. In another example, multiple compute SOC 320, 330, have optical PHY dies 326, 335 that couple with a same LOCM 370 using optical links 388, 392. In yet another example multiple compute SOC 320, 330 may couple with multiple LOCMs 340, 350, 360, 370 using optical links 382, 384, 386, 388, 392, 390, 394, 396. In other embodiments, a compute SOC 320 may include multiple compute chips 322 (not shown) coupled with various optical PHY dies (not shown).

In this way, physical disaggregation of LOCM 340, 350, 360, 370 from compute SOC's 320, 330 may enable different configurations of access to memory which otherwise would not be possible. As a result, a system 300 may be designed to optimize access among different optical PHY ports to improve overall system 300 performance. In system 300, the lengths of the optical connections 382, 384, 386, 388, 390, 392, 394, 396 may be of varying amounts, for example from 1 to 3 meters, even up to a kilometer or more, depending on the type of optical laser and corresponding fiber used, e.g. multimode fiber (MMF) versus single mode fiber (SMF), and depending upon the configuration and performance requirements of the system 300.

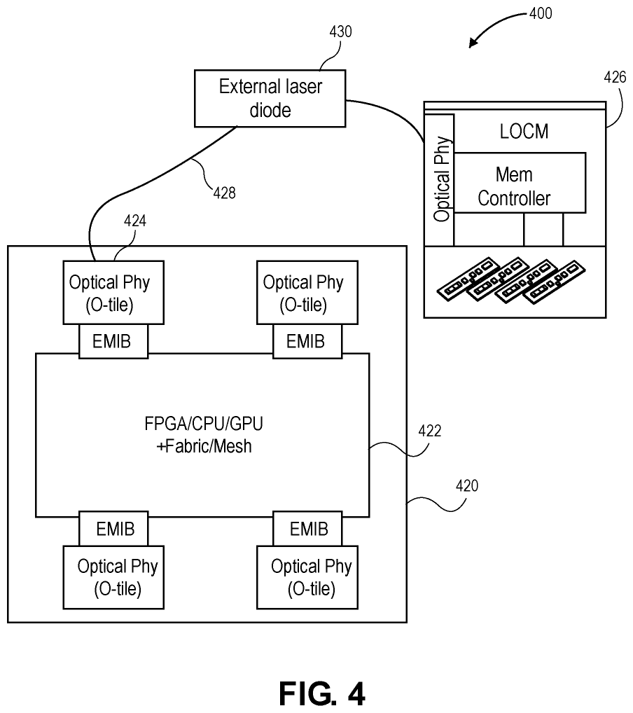

FIG. 4 illustrates an example of a SOC coupled with an LOCM using an external laser diode, in accordance with embodiments. System 400 shows a compute SOC 420, which may be similar to compute SOC 320 of FIG. 3, with compute chip 422 that is coupled with an optical PHY 424. An optical connector 428 couples the optical PHY 424 with the LOCM 426. If the length of the optical connector 428 is less than 1 meter, the optical connector 428 may include an external laser diode 430. This may result in both cost and energy savings for the system 400.

In embodiments, the external laser diode 430 may be based on a laser diode chip which may have one end that is anti-reflection coated, with a laser resonator completed with the collimating lens and an external mirror. Other embodiments may use other structures for the external laser diode 430.

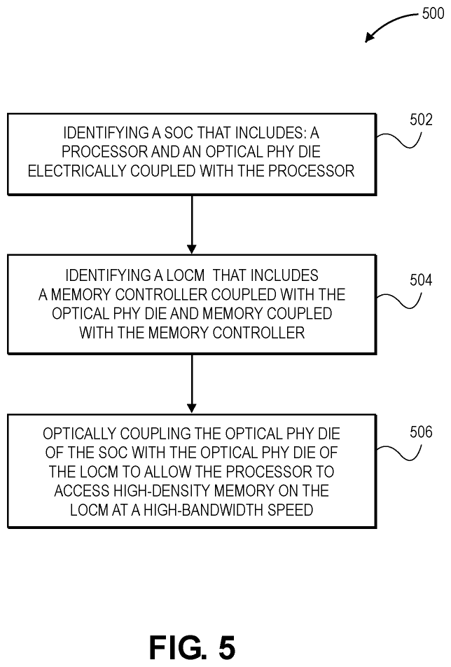

FIG. 5 illustrates an example process implementing a system that includes off-package, high-density, high bandwidth memory access using an optical link, in accordance with embodiments. Process 500 may be implemented by one or more techniques described herein and also with respect to FIGS. 1-4.

At block 502, the process may include identifying a SOC package that includes: a processor and an optical PHY die electrically coupled with the processor. In embodiments, the SOC package may be similar to SOC 200 of FIG. 2, compute SOCs 320, 330 of FIG. 3, or compute SOC 420 of FIG. 4.

In embodiments, the processor may be similar to chip 202 of FIG. 2, and may include a CPU with one or more cores, a FPGA, a GPU, or any ASIC or APU that supports a fabric, mesh, or acceleration function. In embodiments, the processor may include some other compute device. In embodiments, the optical PHY die may be similar to optical PHY die 208, which may also be referred to as an optical tile, of FIG. 2. In embodiments, the PHY die is used to connect a link layer device to a physical medium, such as with an optical fiber 240 of FIG. 2.

In embodiments, the processor may be coupled with the optical PHY die 208 using an EMIB, or using some other silicon or non-silicon interconnect structure. In embodiments, there may be multiple optical PHY dies 208 that may be coupled, respectively, with multiple processors such as chip 202 of FIG. 2

At block 504, the process may further include identifying a LOCM package that includes a memory controller coupled with the optical PHY die and memory coupled with the memory controller. In embodiments, the LOCM package may be similar to LOCM 250 of FIG. 2, LOCM 340, 350, 360, 370 of FIG. 3, or LOCM 426 of FIG. 4. In embodiments, there may be multiple LOCM packages similar to LOCM 250 that may be coupled with multiple SOC packages similar to SOC 200 of FIG. 2.

At block 506, the process may further include optically coupling the optical PHY die of the SOC with the optical PHY die of the LOCM to allow the processor to access high-density memory on the LOCM at a high-bandwidth speed. In embodiments, the optical PHY die of the SOC may include optical PHY die 208 of FIG. 2, or optical PHY dies 324, 325, 326, 327, 334, 335, 336, 337 of FIG. 3, or optical PHY die for 424 of FIG. 4. In embodiments, the optical PHY die of the LOCM may include optical PHY 252 of FIG. 2, optical PHY 342, 344, 352, 362, 372, 374 of FIG. 3, or optical PHY as show on LOCM 426 of FIG. 4.

Embodiments may further include additional processes or portions of processes. For example embodiments may include optically coupling the SOC with the LOCM may be performed using an optical fiber or multiple optical fibers. In embodiments, coupling the SOC with the LOCM may further include coupling using an external laser diode.

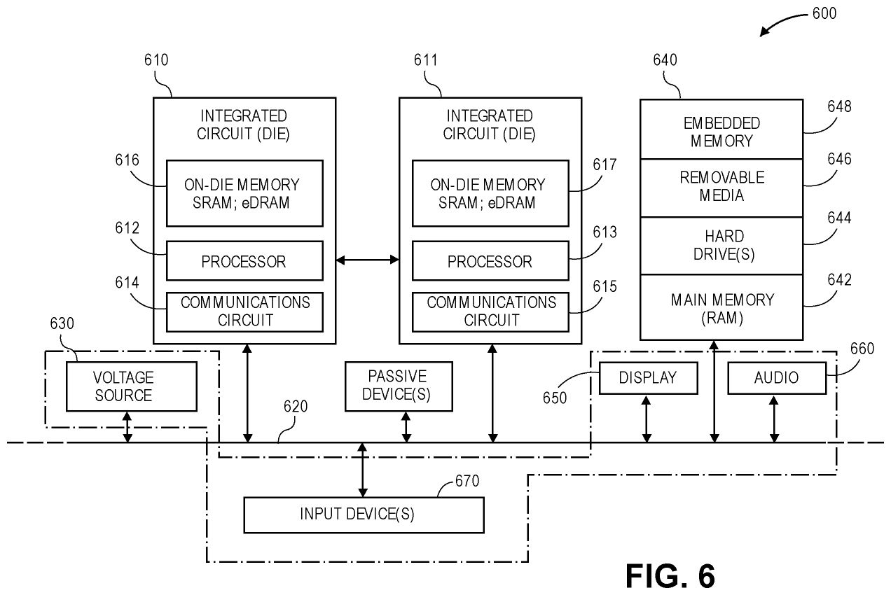

FIG. 6 schematically illustrates a computing device, in accordance with embodiments. The computer system 600 (also referred to as the electronic system 600 ) as depicted can embody off-package, high-density, high-bandwidth memory access using optical links, according to any of the several disclosed embodiments and their equivalents as set forth in this disclosure. The computer system 600 may be a mobile device such as a netbook computer. The computer system 600 may be a mobile device such as a wireless smart phone. The computer system 600 may be a desktop computer. The computer system 600 may be a hand-held reader. The computer system 600 may be a server system. The computer system 600 may be a supercomputer or high-performance computing system.

In an embodiment, the electronic system 600 is a computer system that includes a system bus 620 to electrically couple the various components of the electronic system 600. The system bus 620 is a single bus or any combination of busses according to various embodiments. The electronic system 600 includes a voltage source 630 that provides power to the integrated circuit 610. In some embodiments, the voltage source 630 supplies current to the integrated circuit 610 through the system bus 620.

The integrated circuit 610 is electrically coupled to the system bus 620 and includes any circuit, or combination of circuits according to an embodiment. In an embodiment, the integrated circuit 610 includes a processor 612 that can be of any type. As used herein, the processor 612 may mean any type of circuit such as, but not limited to, a microprocessor, a microcontroller, a graphics processor, a digital signal processor, or another processor. In an embodiment, the processor 612 includes, or is coupled with, off-package, high-density, high-bandwidth memory access using optical links, as disclosed herein. In an embodiment, SRAM embodiments are found in memory caches of the processor. Other types of circuits that can be included in the integrated circuit 610 are a custom circuit or an application-specific integrated circuit (ASIC), such as a communications circuit 614 for use in wireless devices such as cellular telephones, smart phones, pagers, portable computers, two-way radios, and similar electronic systems, or a communications circuit for servers. In an embodiment, the integrated circuit 610 includes on-die memory 616 such as static random-access memory (SRAM). In an embodiment, the integrated circuit 610 includes embedded on-die memory 616 such as embedded dynamic random-access memory (eDRAM).

In an embodiment, the integrated circuit 610 is complemented with a subsequent integrated circuit 611. Useful embodiments include a dual processor 613 and a dual communications circuit 615 and dual on-die memory 617 such as SRAM. In an embodiment, the dual integrated circuit 610 includes embedded on-die memory 617 such as eDRAM.

In an embodiment, the electronic system 600 also includes an external memory 640 that in turn may include one or more memory elements suitable to the particular application, such as a main memory 642 in the form of RAM, one or more hard drives 644, and/or one or more drives that handle removable media 646, such as diskettes, compact disks (CDs), digital variable disks (DVDs), flash memory drives, and other removable media known in the art. The external memory 640 may also be embedded memory 648 such as the first die in a die stack, according to an embodiment.

In an embodiment, the electronic system 600 also includes a display device 650, an audio output 660. In an embodiment, the electronic system 600 includes an input device such as a controller 670 that may be a keyboard, mouse, trackball, game controller, microphone, voice-recognition device, or any other input device that inputs information into the electronic system 600. In an embodiment, an input device 670 is a camera. In an embodiment, an input device 670 is a digital sound recorder. In an embodiment, an input device 670 is a camera and a digital sound recorder.

As shown herein, the integrated circuit 610 can be implemented in a number of different embodiments, including a package substrate having off-package, high-density, high-bandwidth memory access using optical links, according to any of the several disclosed embodiments and their equivalents, an electronic system, a computer system, one or more methods of fabricating an integrated circuit, and one or more methods of fabricating an electronic assembly that includes a package substrate having off-package, high-density, high-bandwidth memory access using optical links, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having off-package, high-density, high-bandwidth memory access using optical links embodiments and their equivalents. A foundation substrate may be included, as represented by the dashed line of FIG. 6. Passive devices may also be included, as is also depicted in FIG. 6.

The following paragraphs describe examples of various embodiments.

### EXAMPLES

Example 1 is a package comprising: a system on chip (SOC); an optical physical layer (PHY) die electrically coupled with the SOC; and wherein the optical PHY die is to optically couple with a PHY die on another package to use an optical link to provide high-bandwidth communication between the SOC and the other package.

Example 2 may include the package of example 1, wherein the optical PHY die is coupled with the SOC using a selected one of: an embedded multi-die interconnect bridge (EMIB) or an interposer.

Example 3 may include the package of example 1, wherein the PHY die is multiple PHY dies.

Example 4 may include the package of example 3, wherein the multiple PHY dies are to optically couple, respectively, to multiple PHY dies on the other package.

Example 5 may include the package of example 3, wherein the other package includes multiple other packages that include one or more PHY dies; and wherein the multiple PHY dies are to optically couple, respectively, to a subset of the one or more PHY dies of the multiple other packages.

Example 6 may include the package of any one of examples 1-5, wherein the other package is a large optically connected memory device (LOCM) that includes: a memory controller coupled with the optical PHY die; and memory coupled with the memory controller.

Example 7 may include the package of example 6, wherein the memory further includes double data rate (DDR) memory, graphics double data rate (GDDR) memory, or memory card reader (MCR).

Example 8 may include the package of example 1, wherein high-bandwidth includes speeds of 1 terabit (Tb) or greater; and wherein the density of the memory is 16 gigabits (Gb) or greater.

Example 9 may include the package of any one of examples 6-8, wherein the optical PHY die is an optical tile.

Example 10 may be a package comprising: an optical physical layer (PHY) die; a system on chip (SOC) electrically coupled with the PHY die, wherein the SOC includes: a memory controller; and memory coupled with the memory controller; and wherein the optical PHY die is to optically couple with a PHY die on another package to use an optical link to provide high-bandwidth memory access between the SOC and the other package.

Example 11 may include the package of example 10, wherein the memory further includes double data rate (DDR) memory, graphics double data rate (GDDR) memory, or memory card reader (MCR).

Example 12 may include the package of example 10, wherein the SOC further includes a processor coupled with the memory controller and the memory.

Example 13 may include the package of example 10, wherein the optical PHY die is multiple optical PHY dies.

Example 14 may include the package of example 13, wherein the multiple optical PHY dies are to optically couple, respectively, to multiple PHY dies on the other package.

Example 15 may include the package of example 14, wherein the other package includes multiple other packages that include one or more PHY dies; and wherein the multiple optically couple, respectively, to a subset of the one or more PHY dies of the multiple other packages.

Example 16 may be a method for accessing high-bandwidth, high-density memory, the method comprising: identifying a system on chip (SOC) package that includes: a processor; and an optical physical layer (PHY) die electrically coupled with the processor; identifying a large optically connected memory device (LOCM) package that includes: a memory controller coupled with the optical PHY die; and memory coupled with the memory controller; and optically coupling the optical PHY die of the SOC with the optical PHY die of the LOCM to allow the processor to access high-density memory on the LOCM at a high-bandwidth speed.

Example 17 may include the method of example 16, wherein optically coupling the SOC with the LOCM further includes optically coupling with optical fiber.

Example 18 may include the method of example 17, wherein coupling with optical fiber further includes coupling with optical fiber using an external laser diode.

Example 19 may include the method of example 16, wherein the LOCM further includes a processor coupled with the memory controller to process memory requests from the SOC.

Example 20 may include the method of any one of example 16-19, wherein the LOCM is implemented on a SOC.

Example 21 may be a system comprising: a system on chip (SOC) that includes: a processor; and an optical physical layer (PHY) die electrically coupled with the processor; a large optically connected memory device (LOCM) that includes: a memory controller coupled with the optical PHY die; and memory coupled with the memory controller; and wherein the SOC and the LOCM are optically coupled to allow the processor to access the memory on the LOCM.

Example 22 may include the system of example 21, wherein the processor further includes a selected one of: a field programmable gate array (FPGA), a central processing unit (CPU), a graphics processing unit (GPU), a fabric, a mesh, or an accelerator.

Example 23 may include the system of example 21, wherein the memory further includes a selected one of: double data rate (DDR) memory, graphics double data rate (GDDR) memory, or memory card reader (MCR).

Example 24 may include the system of example 21, wherein optically coupled further includes a selected one of: coupled with fiber or coupled with fiber using an external laser diode.

Example 25 may include the system of example 21, wherein the optical PHY die of the SOC includes one or more optical PHY dies, and the optical PHY die of the LOCM includes one or more optical PHY dies; and wherein the one or more optical PHY dies of the SOC are optically coupled, respectively, to the one or more optical PHY dies of the LOCM.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. A package comprising:
a system on chip (SOC);
an optical physical layer (PHY) die electrically coupled with the SOC;
wherein the optical PHY die is to optically couple with a PHY die on another package to use an optical link to provide high-bandwidth communication between the SOC and the other package.

2. The package of claim 1, wherein the optical PHY die is coupled with the SOC using a selected one of: an embedded multi-die interconnect bridge (EMIB) or an interposer.

3. The package of claim 1, wherein the PHY die is multiple PHY dies.

4. The package of claim 3, wherein the multiple PHY dies are to optically couple, respectively, to multiple PHY dies on the other package.

5. The package of claim 3, wherein the other package includes multiple other packages that include one or more PHY dies; and wherein the multiple PHY dies are to optically couple, respectively, to a subset of the one or more PHY dies of the multiple other packages.

6. The package of claim 1, wherein the other package is a large optically connected memory device (LOCM) that includes:
a memory controller coupled with the optical PHY die;
memory coupled with the memory controller.

7. The package of claim 6, wherein the memory further includes double data rate (DDR) memory, graphics double data rate (GDDR) memory, or memory card reader (MCR).

8. The package of claim 1, wherein high-bandwidth includes speeds of 1 terabit (Tb) or greater; and wherein the density of the memory is 16 gigabits (Gb) or greater.

9. The package of claim 1, wherein the optical PHY die is an optical tile.

10. A package comprising:
an optical physical layer (PHY) die;
a system on chip (SOC) electrically coupled with the PHY die, wherein the SOC includes:
a memory controller; and
memory coupled with the memory controller; and
wherein the optical PHY die is to optically couple with a PHY die on another package to use an optical link to provide high-bandwidth memory access between the SOC and the other package.

11. The package of claim 10, wherein the memory further includes double data rate (DDR) memory, graphics double data rate (GDDR) memory, or memory card reader (MCR).

12. The package of claim 10, wherein the SOC further includes a processor coupled with the memory controller and the memory.

13. The package of claim 10, wherein the optical PHY die is multiple optical PHY dies.

14. The package of claim 13, wherein the multiple optical PHY dies are to optically couple, respectively, to multiple PHY dies on the other package.

15. The package of claim 14, wherein the other package includes multiple other packages that include one or more PHY dies; and wherein the multiple optically couple, respectively, to a subset of the one or more PHY dies of the multiple other packages.

16. A method for accessing high-bandwidth, high-density memory, the method comprising:
identifying a system on chip (SOC) package that includes:
a processor; and
an optical physical layer (PHY) die electrically coupled with the processor;
identifying a large optically connected memory device (LOCM) package that includes:
a memory controller coupled with the optical PHY die; and
memory coupled with the memory controller; and
optically coupling the optical PHY die of the SOC with the optical PHY die of the LOCM to allow the processor to access high-density memory on the LOCM at a high-bandwidth speed.

17. The method of claim 16, wherein optically coupling the SOC with the LOCM further includes optically coupling with optical fiber.

18. The method of claim 17, wherein coupling with optical fiber further includes coupling with optical fiber using an external laser diode.

19. The method of claim 16, wherein the LOCM further includes a processor coupled with the memory controller to process memory requests from the SOC.

20. The method of claim 16, wherein the LOCM is implemented on a SOC.

21. A system comprising:
a system on chip (SOC) that includes:
a processor; and
an optical physical layer (PHY) die electrically coupled with the processor;
a large optically connected memory device (LOCM) that includes:
a memory controller coupled with the optical PHY die; and
memory coupled with the memory controller; and
wherein the SOC and the LOCM are optically coupled to allow the processor to access the memory on the LOCM.

22. The system of claim 21, wherein the processor further includes a selected one of: a field programmable gate array (FPGA), a central processing unit (CPU), a graphics processing unit (GPU), a fabric, a mesh, or an accelerator.

23. The system of claim 21, wherein the memory further includes a selected one of: double data rate (DDR) memory, graphics double data rate (GDDR) memory, or memory card reader (MCR).

24. The system of claim 21, wherein optically coupled further includes a selected one of: coupled with fiber or coupled with fiber using an external laser diode.

25. The system of claim 21, wherein the optical PHY die of the SOC includes one or more optical PHY dies, and the optical PHY die of the LOCM includes one or more optical PHY dies; and
wherein the one or more optical PHY dies of the SOC are optically coupled, respectively, to the one or more optical PHY dies of the LOCM.
